(19) United States
(12) Patent Application Publication
(10) Pub. No.: US 2013/0187720 A1
(43) Pub. Date: Jul. 25, 2013

(54) TEMPERATURE COMPENSATION TYPE OSCILLATOR

(71) Applicant: NIHON DEMPA KOGYO CO., LTD., TOKYO (JP)

(72) Inventor: TAKEHITO ISHII, SAITAMA (JP)

(73) Assignee: NIHON DEMPA KOGYO CO., LTD., TOKYO (JP)

(21) Appl. No.: 13/743,336

(22) Filed: Jan. 17, 2013

(30) Foreign Application Priority Data
Jan. 23, 2012 (JP) 2012-010936

(51) Int. Cl. H03L 7/00

(52) U.S. Cl. CPC H03L 7/00
USPC 331/44

(57) ABSTRACT

An oscillator includes a first crystal resonator, a second crystal resonator, a first amplifier circuit for oscillation, a second amplifier circuit for oscillation, a mixer circuit, a frequency selection circuit, and a first frequency conversion circuit. Assuming that resonance frequencies of the first and the second crystal resonators at a reference temperature are respectively F₁ and F₂, and temperature coefficients expressed as a rate of change corresponding to temperatures of the resonance frequencies of the first and the second crystal resonators are respectively A₁ and A₂, the relationship of F₂/F₁≠|A₁/A₂| is satisfied. A signal with a temperature compensated frequency is obtained from the frequency selection circuit.

### CROSS-REFERENCE TO RELATED APPLICATIONS

This application claims the priority benefit of Japan application serial no. 2012-010936, filed on Jan. 23, 2012. The entirety of the above-mentioned patent application is hereby incorporated by reference herein and made a part of this specification.

### TECHNICAL FIELD

This disclosure relates to an oscillator that outputs an oscillation signal with high frequency accuracy without affected by an ambient temperature. Especially, this disclosure relates to a temperature compensation type oscillator that includes a crystal resonator such as a Microelectromechanical Systems (MEMS) resonator as a crystal resonator where a change in the resonance frequency relative to a temperature is comparatively large.

### DESCRIPTION OF THE RELATED ART

A crystal controlled oscillator has been generally used for applications that require high frequency stability. Recently, use of a MEMS oscillator including a MEMS resonator has been considered. The MEMS resonator has been developed accompanied by miniaturization of semiconductor device fabrication technique. For example, a MEMS resonator is disclosed in “Crystal controlled oscillator manufacturers talk about comparison theory of ‘MEMS vs. crystal’, which becomes the subject of heated debates in oscillators, by Takeo Oita NIKKEI MICRODEVICES, No. 268, p 71-76 (October, 2007)”. This publication is hereinafter referred to as non-Patent Literature 1. The MEMS resonator includes a semiconductor (for example, silicon) or a piezoelectric body such as aluminum nitride (AlN), and an electrode or similar on the piezoelectric body, thus forming a crystal resonator. The piezoelectric body is minutely processed with high accuracy, for example, at a size of several μm to several tens μm. For example, a MEMS resonator made of silicon semiconductor includes a resonator and four electrodes that are fabricated using a semiconductor device fabrication technique. The resonator is a silicon layer processed to have a circular plate with a diameter of several tens and two beams extending in the diameter direction of the circular plate where the two beams hold the circular plate. The four electrodes are disposed extremely close to the resonator. The two beams function as movable parts relative to the main body of the resonator formed on the circular plate and supports the main body of the resonator without inhibiting a contour mode vibration of the main body of the resonator. The respective electrodes are disposed at positions where an outer peripheral of the main body of the resonator is equally divided by four. The electrodes are disposed with a gap of, for example, 100 nm from the outer peripheral surface of the resonator. Between each electrode and the main body of the resonator, an electrostatic capacity is formed. In this MEMS resonator, electrostatically-driving the resonator via the electrodes vibrates the resonator at its unique mechanical resonance frequency. The oscillation slightly changes an interval between the resonator and the electrodes, and the electrostatic capacity periodically changes at the resonance frequency. Accordingly, an electrode potential also vibrates at the resonance frequency. Thus, embedding the MEMS resonator into an oscillation circuit obtains an oscillator that outputs a signal corresponding to the resonance frequency of the MEMS resonator, namely, a MEMS oscillator.

The MEMS oscillator can be manufactured using semiconductor device fabrication technique only. This facilitates downsizing and allows fabrication at low cost. The MEMS oscillator also features toughness, and a resonator needs not to be fixedly secured on a container with an adhesive, thus ensuring long-term stability. With the MEMS resonator, in a frequency versus temperature characteristic, which is expressed as a rate of change of the resonance frequency depending on a temperature, a temperature coefficient of the second or higher order term is negligible. However, an absolute value of a primary temperature coefficient is, for example, extremely large compared to a quartz crystal resonator or similar. Therefore, in a MEMS oscillator where any temperature compensation has not been performed, the following problem occurs, an output frequency substantially changes as an ambient temperature changes. In the case where a non-piezoelectric material such as silicon is used for a MEMS resonator, a series equivalent capacity in an equivalent circuit of the crystal resonator is extremely small. Therefore, an output frequency hardly changes even if a value of a load capacitance connected to the crystal resonator is changed. Therefore, a method that compensates a frequency versus temperature characteristic by changing the load capacitance value corresponding to an ambient temperature cannot be employed. A known method changes a resonance frequency of a MEMS resonator by changing a bias voltage applied between the MEMS resonator and electrodes disposed around the MEMS resonator (see Japanese Unexamined Patent Application Publication No. 11-508418 and non-Patent Literature 1). However, this change in the resonance frequency due to the change in the bias voltage is not enough to compensate for the change in the resonance frequency due to an ambient temperature. In the case where a piezoelectric material is used for a MEMS resonator, for example, a MEMS resonator configured as Film Bulk Acoustic Resonator (FBAR) is used, changing a value of a load capacitance connected to the crystal resonator allows changing an output frequency to some extent (see Japanese Unexamined Patent Application Publication No. 2006-318478). In the following description, a temperature coefficient of a resonance frequency represents a primary temperature coefficient in the case where a frequency versus temperature characteristic of a resonance frequency is expressed as a rate of change from a resonance frequency at a reference temperature.

Non-Patent Literature 1 discloses a method for obtaining a constant output frequency using the MEMS oscillator without affected by an ambient temperature. The method (PLL division ratio compensation method) supplies an output from the MEMS oscillator to a frequency synthesizer circuit with a phase-locked loop (a PLL) circuit, and changes a division ratio in a frequency dividing circuit in the PLL circuit corresponding to an ambient temperature (Non-Patent Literature 1). Since this method switches a division ratio corresponding to an ambient temperature, this arises problems that an output frequency changes discontinuously, a phase noise characteristic is poor, and phase continuity in an output signal is not guaranteed. Accordingly, the MEMS oscillator where a temperature compensation is performed using a PLL division ratio compensation method is difficult to employ for, for example, a temperature compensation type crystal controlled oscillator.

Japanese Unexamined Patent Application Publication No. 2007-524303 (i.e., Patent Literature 3) discloses a method where many MEMS oscillators with respective different characteristics are prepared. This method selects some MEMS oscillators among the MEMS oscillators corresponding to an ambient temperature, and adds or subtracts outputs frequencies from the selected MEMS oscillators. Thus, this method obtains a temperature compensated output frequency.

Japanese Unexamined Patent Application Publication No. 2009-65601 (hereinafter referred to as Patent Literature 4) discloses a configuration that employs two MEMS resonators with different frequency versus temperature characteristics and different resonance frequencies. This configuration oscillates the respective MEMS resonators with separate oscillation circuits, and mixes oscillation signals from the MEMS resonators at a mixer circuit. Thus, an output frequency is not changed even if an ambient temperature changes. With a MEMS resonator using silicon, a known method changes a temperature coefficient by forming a silicon oxidized film on the surface of the MEMS resonator. The silicon oxidized film is disposed to perform a temperature compensation for a MEMS resonator alone. Here, assume that a first MEMS resonator has a resonance frequency of 150 MHz and a temperature coefficient of −10 ppm/° C., and a second MEMS resonator has a resonance frequency of 50 MHz and a temperature coefficient of −30 ppm/° C. Although temperature coefficients expressed by ppm differ between the both MEMS resonators, actual changes in frequency values of the both MEMS resonators in accordance with a temperature change match at −1.5 KHz/° C. Here, if an oscillation signal from a first MEMS resonator and an oscillation signal from a second MEMS resonator are mixed in a mixer circuit, and a difference frequency component between the both signals (100 MHz) are extracted, a contribution amount of frequency change due to a temperature change is offset. Thus, a signal of 100 MHz can be obtained without affected by a change in an ambient temperature.

FIG. 5 is a circuit diagram illustrating a configuration of the conventional oscillator using two MEMS resonators. MEMS resonators 11 and 12 are connected to amplifier circuits 13 and 14 for oscillation, respectively. The amplifier circuits 13 and 14 output oscillation signals corresponding to resonance frequencies of the MEMS resonators 11 and 12, respectively. These two oscillation signals are supplied to a mixer circuit 15, and a low-pass filter 16 is disposed at an output of the mixer circuit 15. The low-pass filter 16 extracts a difference frequency component signal obtained from the result of mixing the two oscillation signals. An output from the low-pass filter 16 is an output frequency Fₒᵤₜ.

Assume that a reference temperature T₀ is, for example, 25° C., let resonance frequencies of the MEMS resonators 11 and 12 at the reference temperature be denoted as F₁ and F₂ (MHz). Let the temperature coefficients of the MEMS resonators 11 and 12 be denoted as A₁ and A₂ (ppm/° C.), respectively. Then, a resonance frequency f₁(T) of the MEMS resonator 11 when an ambient temperature is T is expressed by f₁(T)=F₁+A₁(T−T₀)F₁×10⁻⁶ (MHz). Similarity, a resonance frequency f₂(T) of the MEMS resonator 12 at the same ambient temperature T is expressed by f₂(T)=F₂+A₂(T−T₀)F₂×10⁻⁶ (MHz). Even if f₁(T)≧f₂(T) is assumed, the formula has universality. A difference frequency of f₁(T)−f₂(T) between the both resonance frequencies is expressed by f₁(T)−f₂(T)=F₁−F₂+(A₁F₁−A₂F₂) (T−T₀)×10⁻⁶ (MHz). If F₁/F₂=A₂/A₁ is satisfied, A₁F₁=A₂F₂ is given and yields f₁(T)−f₂(T)=F₁−F₂ (MHz). The difference frequency between the both resonance frequencies is always expressed by F₁−F₂, without affected by an ambient temperature. Accordingly, an output frequency Fₒᵤₜ, where a temperature is compensated, is obtained.

However, it is difficult to accurately form a silicon oxidized film or similar on the surface of the MEMS resonator. Also, it is difficult to control a temperature coefficient at a desired value. In the case where a film is formed thick on the surface of the MEMS resonator, a resonance of the MEMS resonator (a Q factor) becomes low. As a result, a frequency in an oscillation signal becomes unstable. Eventually, with the method disclosed in Patent Literature 4, it is difficult to constitute a MEMS oscillator that outputs a constant frequency without affected by a change in an ambient temperature.

The conventional oscillator using a crystal resonator such as a MEMS resonator, where a resonance frequency substantially changes corresponding to a temperature change, has a problem such as the following. When a change in a resonance frequency due to a temperature is compensated to obtain an output at constant frequency without affected by an ambient temperature, it is difficult to obtain a good phase noise characteristic.

A need thus exists for a temperature compensation type oscillator which is not susceptible to the drawback mentioned above.

### SUMMARY

According to an aspect of this disclosure, there is provided an oscillator. The oscillator includes a first crystal resonator, a second crystal resonator, a first amplifier circuit for oscillation, a second amplifier circuit for oscillation, a mixer circuit, a frequency selection circuit, and a first frequency conversion circuit. The first amplifier circuit is combined with the first crystal resonator and configured to output a first oscillation signal. The second amplifier circuit is combined with the second crystal resonator and configured to output a second oscillation signal. The mixer circuit is configured to mix the first oscillation signal with the second oscillation signal. The frequency selection circuit is configured to: select a predetermined frequency component from outputs from the mixer circuit, and output the selected component. The first frequency conversion circuit is configured to perform frequency conversion of the first oscillation signal. The first oscillation signal after the frequency conversion in the first frequency conversion circuit is supplied to the mixer circuit. Assuming that resonance frequencies of the first and the second crystal resonators at a reference temperature are respectively F₁ and F₂, and temperature coefficients expressed as a rate of change corresponding to temperatures of the resonance frequencies of the first and the second crystal resonators are respectively A₁ and A₂, the relationship of F₂/F₁≠|A₁/A₂| is satisfied. A signal with a temperature compensated frequency is obtained from the frequency selection circuit.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is a circuit diagram illustrating a configuration of a temperature compensation type oscillator according to an embodiment of the disclosure;

FIG. 2 is a circuit diagram illustrating a configuration of a temperature compensation type oscillator according to another embodiment of the disclosure;

FIG. 3 is a circuit diagram illustrating a configuration of a temperature compensation type oscillator according to the disclosure where an electrostatic drive bias voltage applied to the crystal resonator is variable;

FIG. 4 is a circuit diagram illustrating a configuration of a temperature compensation type oscillator according to the disclosure where a variable capacitance element is connected to the crystal resonator; and

FIG. 5 is a circuit diagram illustrating a configuration of a conventional oscillator that employs two MEMS resonators.

### DETAILED DESCRIPTION

The preferred embodiments of the disclosure will be described with referring to the drawings.

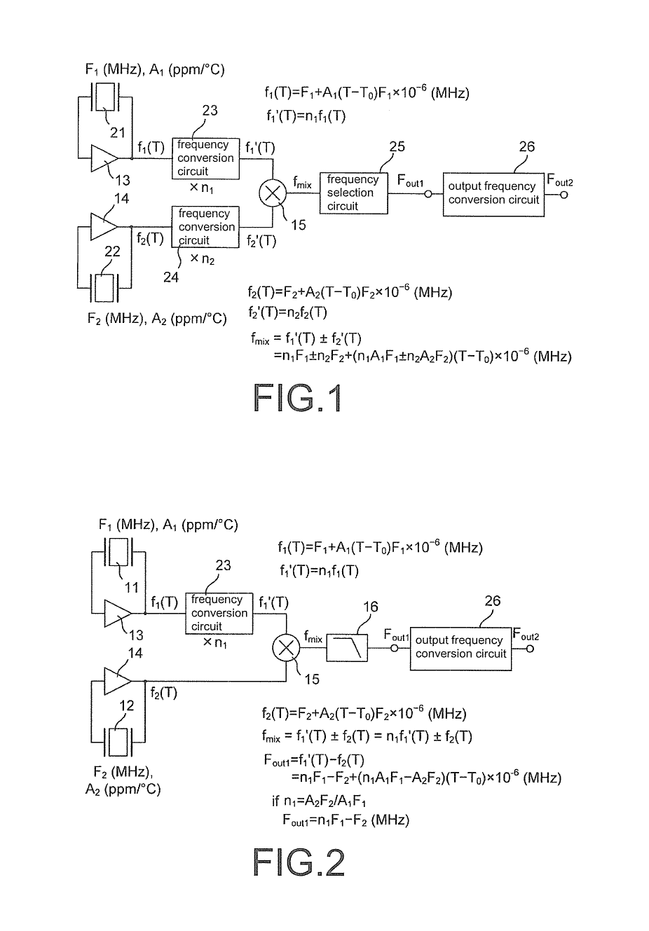

A temperature compensation type oscillator illustrated in FIG. 1 is a principle configuration of an oscillator according to the disclosure.

The oscillator includes two crystal resonators 21 and 22. The following is assumed here. Resonance frequencies of the crystal resonators 21 and 22 at a reference temperature T₀ (for example, 25° C.) are F₁ and F₂ (MHz), respectively. The crystal resonators 21 and 22 have temperature coefficients of A₁ and A₂ (ppm/° C.), respectively. Here, let it be assumed that F₁/F₂≠|A₂/A₁|.

The crystal resonator 21 is interposed between an input and an output of an amplifier circuit 13 for oscillation. The amplifier circuit 13 vibrates the crystal resonator 21 as a resonance element to output an oscillation signal. The resonance frequency of the crystal resonator 21 has a temperature dependence expressed using a temperature coefficient A₁. Hence, a frequency f₁ (T) of the oscillation signal is also a function of a temperature T, and is expressed by f₁(T)=F₁+A₁(T−T₀)F₁×10⁻⁶ (MHz). The oscillation signal from the amplifier circuit 13 is supplied to a frequency conversion circuit 23. The frequency conversion circuit 23 includes a frequency synthesizer circuit with a PLL circuit of a fractional-N type. Let a division ratio of the PLL circuit be denoted as n₁. The frequency conversion circuit 23 multiplies a frequency f₁(T) of an oscillation signal, which is output from the amplifier circuit 13, by n₁. Then, the frequency conversion circuit 23 outputs the multiplied signal as a signal of the frequency f₁′(T). The frequency conversion circuit 23 may employ a fractional multiplication circuit. Similarly, the crystal resonator 22 is interposed between an input and an output of an amplifier circuit 14 for oscillation. The amplifier circuit 14 oscillates the crystal resonator 22 as a resonance element and outputs an oscillation signal expressed by a frequency f₂(T). The f₂(T) is a function of temperature and is expressed by f₂(T)=F₂+A₂(T−T₀)F₂×10⁻⁶ (MHz). The oscillation signal from the amplifier circuit 14 is supplied to the frequency conversion circuit 24, which includes a frequency synthesizer circuit with the PLL circuit of a fractional-N type where a division ratio is n₂, or a fractional multiplication circuit. The frequency conversion circuit 24 multiplies the frequency f₂(T) of the oscillation signal, which is output from the amplifier circuit 14, by n₂ and outputs the multiplied signal as a signal of the frequency f₂′(T). The frequency multiplication ratios n₁ and n₂ are generally expressed by a positive rational number.

The temperature compensation type oscillator includes a mixer circuit 15. The mixer circuit 15 inputs signals from the respective frequency conversion circuits 23 and 24, and generates signals with frequencies corresponding to a sum frequency and a difference frequency of the input signals. Assume that a frequency of the signal output from the mixer circuit 5 is fₘᵢₓ, fₘᵢₓ is expressed by fₘᵢₓ=f₁′(T)±f₂′(T). In the double sign (±), “+” corresponds to a sum frequency, and “−” corresponds to a difference frequency. Since f₁′(T)=n₁f₁(T) and f₂′(T) =n₂f₂(T) are given, the following formula is obtained.

fₘᵢₓ=f₁′(T)±f₂′(T)

f₁′(T)±f₂′(T)=n₁F₁±n₂F₂+(n₁A₁F₁±n₂A₂F₂) (T−T₀)×10⁻⁶ (MHz)

From this formula, n₁/n₂=−(A₂F₂/A₁F₁) is satisfied insofar as values of the temperature coefficients A₁ and A₂ have different signs. Hence, n₁A₁F₁+n₂A₂F2=0 is given by appropriately selecting the multiplication ratios n₁ and n₂, and the sum frequency is expressed by n₁F₁+n₂F₂ without affected by a temperature. That is, as a temperature compensated output frequency, a sum frequency component from the mixer circuit 15 may be used. Similarity, n₁/n₂=−(A₂F₂/A₁F₁) is satisfied insofar as values of the temperature coefficients A₁ and A₂ have the same sign. Hence, n₁A₁F₁−n₂A₂F₂=0 is given by appropriately selecting the multiplication ratios n₁ and n₂, and the difference frequency is expressed by n₁F₁−n₂F₂ without affected by a temperature. That is, as a temperature compensated output frequency, a difference frequency component from the mixer circuit 15 may be used.

The multiplication ratios n₁ and n₂ of the frequency conversion circuits 23 and 24 are determined as described above, based on F₁, F₂, A₁, and A₂, which are actually measured at the two crystal resonators 21 and 22. This holds either of the sum frequency or the difference frequency, which is output from the mixer circuit 15, at a constant frequency even if an ambient temperature changes. A frequency selection circuit 25 is disposed at an output of the mixer circuit 15. The frequency selection circuit 25 selects either of the sum frequency component or the difference frequency component for which a temperature is compensated as described above, and outputs the selected component as an output frequency Fₒᵤₜ₁. The frequency selection circuit 25 may include, for example, a low-pass filter (for selecting a difference frequency component), a high-pass filter (for selecting a sum frequency component), or a band-pass filter.

When fabricating a crystal resonator, it is difficult to precisely control a temperature coefficient, setting aside the question of the resonance frequency. With the oscillator illustrated in FIG. 1, when the multiplication ratios n₁ and n₂ are determined based on F₁, F₂, A₁, and A₂, which are actually measured at the crystal resonators 21 and 22, and therefore an output frequency Fₒᵤₜ₁ for which a temperature is accurately compensated is obtained, the output frequency Fₒᵤₜ₁ may not match a frequency desired by a user. In the case where the output frequency Fₒᵤₜₛ does not match the desired frequency, an output frequency conversion circuit 26 may be provided. The output frequency conversion circuit 26 further converts the output frequency Fₒᵤₜ₁ and yields a final output frequency Fₒᵤₜ₂. The output frequency conversion circuit 26 can be built with, for example, a frequency synthesizer circuit including a PLL circuit of a fractional-N type, or a fractional multiplication circuit.

The oscillator illustrated in FIG. 1 includes the two frequency conversion circuits 23 and 24, and performs frequency conversion of oscillation signals of the frequencies f₁(T) and f₂(T) so as to obtain higher frequencies f₁′(T) and f₂′(T). Use of a difference frequency (f₁′(T)−f₂′(T)) as an output frequency Fₒᵤₜ₁ makes the frequency of the sum frequency (f₁′(T)+f₂′(T)) much larger than the frequency of the difference frequency. Therefore, when a low-pass filter or similar filter is used as the frequency selection circuit 25, the filter can be easily designed and downsized. This allows the filter, for example, to be incorporated into an integrated circuit. As a result, the amplifier circuits 13 and 14 for oscillation, the frequency conversion circuits 23 and 24, the mixer circuit 15, the frequency selection circuit 25, and the output frequency conversion circuit 26 can be easily constituted as a single integrated circuit (an IC) chip or a large scale integrated circuit (an LSI) chip using a single semiconductor substrate. Use of MEMS resonators as the crystal resonators 21 and 22 allows the crystal resonators 21 and 22 to be incorporated into the IC chip or the LSI chip.

In the example illustrated in FIG. 1, a temperature compensated output frequency Fₒᵤₜ₁ may be obtained on condition that n₁/n₂=A₂F₂/A₁F₁ or n₁/n₂=−(A₂F₂/A₁F₁) is satisfied. The two conditions can be summarized as n₁/n₂ =|A₂F₂/A₁F₁|. Apparently, this expression can be satisfied even if either of n₁ or n₂ is set to 1. Accordingly, even if one of the frequency conversion circuits 23 and 24 is not provided, the temperature compensated output frequency Fₒᵤₜ₁ is obtained.

FIG. 2 illustrates an exemplary specific configuration of the oscillator according to the disclosure. FIG. 2 illustrates the oscillator that employs the MEMS resonators 11 and 12 as two crystal resonators in the configuration in FIG. 1 where installation of the frequency conversion circuit 24 is omitted. Accordingly, the frequency conversion circuit 23 supplies the signal of the frequency f₁′(T) to the mixer circuit 15, and the amplifier circuit 14 supplies the oscillation signal of the frequency f₂(T) to the mixer circuit 15. In this case, since the values of the temperature coefficients A₁ and A₂ of the MEMS resonators 11 and 12 have the same sign, the difference frequency (f₁′(T)−f₂(T)) may be selected from the output fₘᵢₓ of the mixer circuit 15. Thus, the low-pass filter 16 is used as the frequency selection circuit.

To change a temperature coefficient in the MEMS resonator, for example, in the case where the MEMS resonator is made of a silicon material, the following method may be employed. This method forms a silicon oxidized film as a temperature compensation material on the surface of the crystal resonator, and controls a thickness of the silicon oxidized film. The resonance frequency of the MEMS resonator depends on a size of the crystal resonator, but it is difficult to substantially change the crystal resonator size due to fabrication reasons. For this, the resonance frequency of the MEMS resonator cannot be substantially changed in the same mode of vibration. To substantially change the resonance frequencies between the two MEMS resonators, for example, one MEMS resonator may be driven in a basic vibration mode while the other MEMS resonator may be driven in a spurious mode.

In the oscillator illustrated in FIG. 2, Fₒᵤₜ₁ is expressed as follows.

Fₒᵤₜ₁=n₁f₁(T)−f₂(T)

nᵢf₁(T)−f₂(T)=n₁F₁−F₂+(n₁A₁F₁−A₂F₂) (T−T₀)×10⁻⁶ (MHz).

If n₁=A₂F₂/A₁F₂ is given, Fₒᵤₜ₁ is expressed by Fₒᵤₜ₁=n₁F₁−F₂, the temperature compensated output frequency Fₒᵤₜ₁ is thus obtained.

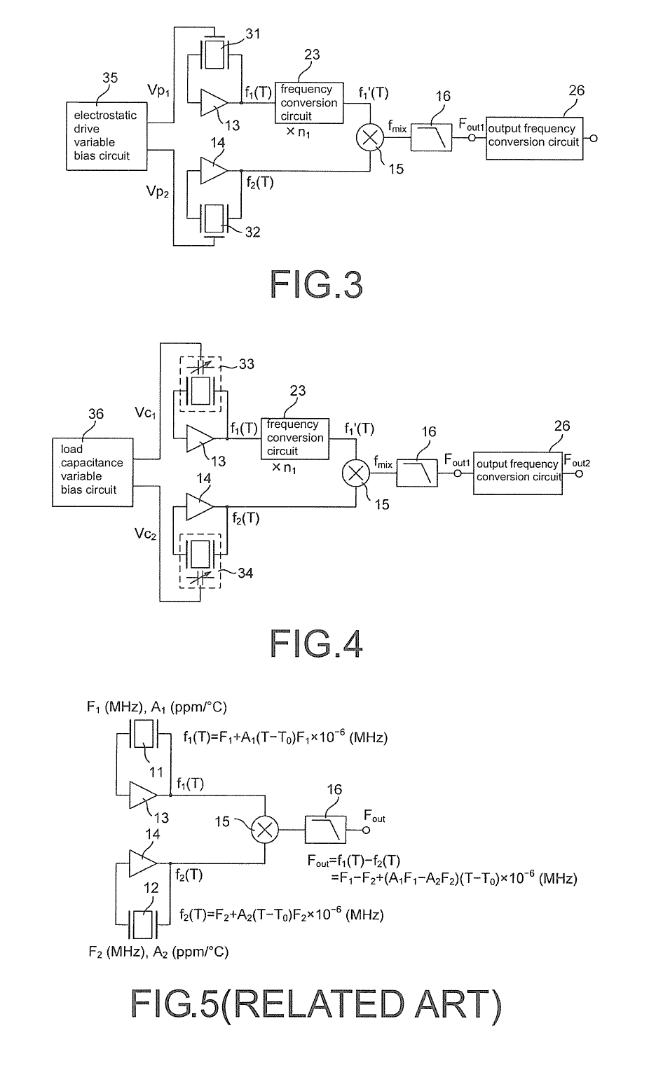

FIG. 3 illustrates an exemplary oscillator that employs the MEMS resonators 31 and 32 made of a silicon material as the MEMS resonators 11 and 12 in the configuration in FIG. 2. With the MEMS resonators 31 and 32 made of a silicon material, the resonance frequencies can be slightly changed by changing a bias voltage for an electrostatic drive, which is applied to the crystal resonators. To finely adjust the output frequency or compensate a contribution of a coefficient of the second or higher order term in the frequency versus temperature characteristic of the crystal resonators, an electrostatic drive variable bias circuit 35 is provided. The electrostatic drive variable bias circuit 35 independently controls values of the bias voltages for electrostatic drive Vp₁ and Vp₂, which are applied to the respective two MEMS resonators 31 and 32.

FIG. 4 illustrates an exemplary oscillator that employs the MEMS resonators 33 and 34 made of a piezoelectric material as the MEMS resonators 11 and 12 in the configuration in FIG. 2. In the MEMS resonators 33 and 34 made of a piezoelectric material, the resonance frequencies can be slightly changed by connecting variable capacitance elements such as variable capacitance diodes as load capacitances to the crystal resonators and changing the load capacitance value. The MEMS resonators 33 and 34, to which variable capacitance elements are electrically connected as load capacitances, are also employed. In the configuration illustrated in FIG. 4, a load capacitance variable bias circuit 36 is provided to finely adjust an output frequency or to compensate a contribution of the coefficient of the second or higher order term in the frequency versus temperature characteristic of the crystal resonator. The load capacitance variable bias circuit 36 independently controls values of bias voltages Vc₁ and Vc₂ that are applied to the variable capacitance elements of the two MEMS resonators 33 and 34, respectively.

Exemplary drawings illustrated in FIGS. 2 to 4 use MEMS resonators as crystal resonators. However, the crystal resonator used in the oscillator according to the disclosure should not be construed in a limiting sense. Any kind of crystal resonator is applicable.

The oscillator according to the disclosure may further include a second frequency conversion circuit configured to perform a frequency conversion of the second oscillation signal. The oscillator may be configured such that the second oscillation signal, which is a signal after the frequency conversion is performed in the second frequency conversion circuit, may be supplied to a mixer circuit.

In the case where two crystal resonators with respective resonance frequencies F₁ and F₂ and respective temperature coefficients A₁ and A₂ at a reference temperature T₀ are used, an amplifier circuit for oscillation is provided for each crystal resonator, and a difference frequency between oscillation signals from respective amplifier circuits without a frequency conversion circuit is set as an output frequency, and F₂/F₁=A₁/A₂ is given, a constant output frequency can be obtained without affected by an ambient temperature. The relationship is not limited to the case where a crystal resonator is a MEMS resonator, but is generally applied insofar as the temperature coefficients A₁ and A₂ have the same sign (that is, A₁A₂>0). If the temperature coefficients of the two crystal resonators have different signs (A₁A₂<0), considering the sum frequency of the resonance frequencies f₁(T) and f₂(T), f₁(T)+f₂(T)=F₁+F₂ (MHz) is satisfied if F₁A₁+F₂A₂ =0, that is, F₁/F₂=−(A₂/A₁) is given. The sum frequency is always expressed by F₁+F₂ without affected by an ambient temperature. Thus, a constant output frequency, which is not affected by an ambient temperature, is obtained. In short, when the temperature coefficients A₁ and A₂ have the same sign and different signs, F₁/F₂>0 is given. Assume that |•| is a sign that denotes an absolute value. When F₁/F₂=|A₂/A₁| is given, a constant output frequency can be obtained without affected by an ambient temperature by obtaining a difference frequency or a sum frequency between the resonance frequencies f₁(T) and f₂(T) in a mixer circuit or similar. However, it is difficult to precisely control a temperature coefficient, especially in a crystal resonator. Eventually, it is difficult to obtain a temperature compensated output frequency where two crystal resonators are formed such that F₁/F₂=|A₂/A₁| is satisfied.

In contrast, the oscillator according to the disclosure, a frequency conversion circuit is disposed at an output of at least one side of the two amplifier circuits, and a frequency of the oscillation signal is converted in the frequency conversion circuit. In the case where a frequency synthesizer circuit with a PLL circuit, or a fractional multiplication circuit is used as a frequency conversion circuit, even if the frequency conversion circuit is passed through, the temperature coefficient of an oscillation signal does not change. For example, assume that the frequency conversion circuit is disposed at an output of the amplifier circuit for the first crystal resonator, and a division ratio of the PLL circuit there is regarded as n₁. Considering a frequency at a reference temperature, the frequency conversion circuit converts the resonance frequency F₁ into a frequency F₁′(=n₁F₁) (that is, the frequency is multiplied by n₁.) while the temperature coefficient A₁ remains the same. Even if F₂/F₁≠|A₁/A₂| is given, F₂/F₁′=|A₁/A₂| is satisfied by appropriately setting the multiplication ratio n₁ in the frequency conversion circuit. Accordingly, the difference frequency or the sum frequency between an oscillation signal from the frequency conversion circuit (the frequency F₁′ at the reference temperature) and an oscillation signal from the other crystal resonator (the frequency F₂ at the reference temperature) becomes constant without affected by the ambient temperature. In short, a temperature compensation type oscillator is configured without using a crystal resonator where a temperature coefficient is precisely controlled at a desired value. This applies when frequency conversion circuits are disposed at respective outputs of the two amplifier circuits for oscillation.

The oscillator according to the disclosure includes the frequency conversion circuit. A multiplication ratio in the frequency conversion circuit is determined corresponding to parameters unique to each crystal resonator (resonance frequency and a temperature coefficient at a reference temperature) and does not change corresponding to an ambient temperature. Thus, the oscillator according to the disclosure does not discontinuously change an output frequency. This guarantees phase continuity in an output signal, thus ensuring a good phase noise characteristic.

According to the disclosure, various crystal resonators such as a MEMS resonator and quartz crystal resonator may be employed as crystal resonators. Among two crystal resonators, one crystal resonator may be driven in a basic vibration mode, and the other crystal resonator may be driven in a spurious mode. In the case where the MEMS resonator is used as the crystal resonator, for example, the MEMS resonator may be made of a silicon material or a piezoelectric material.

With the oscillator according to the disclosure, the multiplication ratio in the frequency conversion circuit is determined such that a difference frequency or a sum frequency may be constant corresponding to the resonance frequencies F₁ and F₂ of the respective crystal resonators and the temperature coefficients A₁ and A₂ of the respective crystal resonators at a reference temperature without affected by an ambient temperature. However, an output frequency itself, which is obtained from the result, does not always match a desired frequency. To obtain a desired output frequency in the end, it is preferred that a frequency conversion circuit be further connected to an output of the frequency selection circuit, which selects a component of a predetermined frequency, that is, a component of a difference frequency or a sum frequency, from outputs from the mixer circuit and then outputs the selected component.

In the case where a temperature compensated output frequency is obtained using two crystal resonators, which have different resonance frequencies and different temperature coefficients, this disclosure describes the following effects. The use of the frequency conversion circuit, which holds a multiplication ratio using a parameter unique to each crystal resonator, eliminates the need for strict setting such as a temperature coefficient or each crystal resonator and also avoids difficulty in fabrication of the crystal resonator. Thus, an oscillator that features both good phase noise characteristic and a temperature characteristic is provided.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. An oscillator, comprising:
a first crystal resonator;
a second crystal resonator;
a first amplifier circuit for oscillation, the first amplifier circuit being combined with the first crystal resonator and configured to output a first oscillation signal;
a second amplifier circuit for oscillation, the second amplifier being combined with the second crystal resonator and configured to output a second oscillation signal;
a mixer circuit, configured to mix the first oscillation signal with the second oscillation signal;
a frequency selection circuit, configured to select a predetermined frequency component from outputs of the mixer circuit, and output the selected predetermined frequency component; and
a first frequency conversion circuit, configured to perform a frequency conversion of the first oscillation signal; wherein
the first oscillation signal after the frequency conversion in the first frequency conversion circuit is supplied to the mixer circuit,
denoting that resonance frequencies of the first and the second crystal resonators at a reference temperature are respectively F₁ and F₂, and temperature coefficients expressed as a rate of change corresponding to temperatures of the resonance frequencies of the first and the second crystal resonators are respectively A₁ and A₂, a relationship of F₂/F₁≠|A₁/A₂| is satisfied, and
a signal with a temperature compensated frequency is obtained from the frequency selection circuit.

2. The oscillator according to claim 1, further comprising:
an output frequency conversion circuit, configured to perform a frequency conversion of the signal output from the frequency selection circuit, so as to output the converted signal as a final output frequency signal.

3. The oscillator according to claim 1, further comprising:
a second frequency conversion circuit, configured to perform a frequency conversion of the second oscillation signal, wherein
the second oscillation signal after the frequency conversion in the second frequency conversion circuit is supplied to the mixer circuit.

4. The oscillator according to claim 2, further comprising:
a second frequency conversion circuit, configured to perform a frequency conversion of the second oscillation signal, wherein
the second oscillation signal after the frequency conversion in the second frequency conversion circuit is supplied to the mixer circuit.

5. The oscillator according to claim 1, wherein
the first and the second crystal resonators are configured as MEMS resonators using a silicon material.

6. The oscillator according to claim 1, wherein
the first and the second crystal resonators are configured as MEMS resonators using a piezoelectric material.

7. The oscillator according to claim 5, further comprising:
a variable bias circuit, configured to generate a bias voltage for electrostatic drive, the bias voltage being applied to the first and the second crystal resonators.

8. The oscillator according to claim 6, further comprising:
a first and a second variable capacitance elements, being respectively electrically connected to the first and second crystal resonators, the first and the second variable capacitance elements having respective capacity values changed by bias voltages applied to the first and the second crystal resonators, and
a load capacitance variable bias circuit, configured to generate the bias voltages.

9. The oscillator according to claim 5, wherein
the frequency selection circuit includes a low-pass filter or a band-pass filter.

10. The oscillator according to claim 6, wherein
the frequency selection circuit includes a low-pass filter or a band-pass filter.

11. The oscillator according to claim 7, wherein
the frequency selection circuit includes a low-pass filter or a band-pass filter.

12. The oscillator according to claim 8, wherein
the frequency selection circuit includes a low-pass filter or a band-pass filter.

13. The oscillator according to claim 1, wherein
a temperature compensation material is added to at least one of the first and the second crystal resonators alone.

14. The oscillator according to claim 1, wherein
one of the first and the second crystal resonators is driven in a basic vibration mode, and the other is driven in a spurious mode.

15. The oscillator according to claim 1, wherein
the frequency conversion circuits includes a frequency synthesizer circuit with a PLL circuit or a fractional multiplication circuit.
